(19) United States
(12) Patent Application Publication
(10) Pub. No.: US 2014/0262441 A1
(43) Pub. Date: Sep. 18, 2014

(54) CIRCUIT BOARD WITH SIGNAL ROUTING LAYER HAVING UNIFORM IMPEDANCE

(71) Applicant: HON HAI PRECISION INDUSTRY CO., LTD., New Taipei (TW)

(72) Inventor: KAI-WEN WU, New Taipei (TW)

(73) Assignee: HON HAI PRECISION INDUSTRY CO., LTD., New Taipei (TW)

(21) Appl. No.: 14/014,401

(22) Filed: Aug. 30, 2013

(30) Foreign Application Priority Data
Mar. 13, 2013 (TW) 102108922

(51) Int. Cl. H05K 1/02

(52) U.S. Cl. CPC H05K 1/0253
USPC 174/250

(57) ABSTRACT

A circuit board includes a dielectric layer and a signal routing layer on the dielectric layer. The signal routing layer includes connector traces, chip traces, and signal traces connecting the two. A width of the signal traces is greater than a width of the chip traces, which is less than a width of the connector traces. The dielectric layer includes trace areas of different depths for each type of trace to achieve a uniform impedance throughout all traces.

### BACKGROUND

1. Technical Field

The present disclosure relates to circuit boards, and particularly to a circuit board with signal routing layer having an uniform impedance.

2. Description of Related Art

Wireless radio frequency transceiver technology as a new fiber-optic connector standard is applied to electronic products. Current radio frequency transceivers can reach single-channel speed of 10 Gb/s, and in such a high-frequency transmission impedance matching becomes particularly important. If there is an impedance mismatch, very large amounts of energy will be lost and the bit error rate increased, so the impedance matching design is very, important in the wireless radio frequency transceiver. Existing technology can influence the circuit design of a high-frequency circuit to change the impedance, but in order to achieve the connected circuit impedance matching, this matching method is complicated. In addition, in changing the circuit design, errors inevitably arise. This results in impedance matching which is not ideal.

Therefore, it is desirable to provide a circuit board which can overcome the above-mentioned limitation.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

FIG. 1 is a schematic, sectional view of an embodiment of a circuit board with signal routing layer having a uniform impedance.

FIG. 2 is a schematic view of the signal routing layer of the circuit board shown in FIG. 1.

### DETAILED DESCRIPTION

FIGS. 1-2 show a circuit board 10 according to an exemplary embodiment. The circuit board 10 includes a signal routing layer 11, a dielectric layer 12, and a ground layer 13. In this embodiment, the signal routing layer 11 comprehends all conductor wires arrayed on the circuit board 10.

In the practical requirement, the circuit board 10 also includes conductor layers. In this embodiment, the conductor layer is not shown in FIG. 1.

The signal routing layer 11 and the ground layer 13 are located on two opposite surfaces of the dielectric layer 12. In other words, the dielectric layer 12 is sandwiched between the signal routing layer 11 and the ground layer 13.

The signal routing layer 11 connects to electronic components, such as ball grid arrays (BGAs), resistors, and capacitors, for example. The signal routing layer 11 includes a number of signal traces 111, a number of chip traces 112, and a number of connector traces 113. Each of the signal traces 111 directly connects a respective one of the chip traces 112 to a respective one of the connector traces 113. The chip traces 112 terminate in chips, such as CPUs. The connector traces 113 are connected to connectors, such as USB connectors.

Each of the signal traces 111 is a single strip. Each of the chip traces 112 is a single strip. Each of the connector traces 113 is a single strip. A width of the signal trace 111 is greater than a width of the chip trace 112, while the width of the signal trace 111 is less than a width of the connector trace 113. In the formula R=ρL/A, R is the resistance value (unit is the ohm) of the signal trace 111, of the chip trace 112, or of the connector trace 113, and ρ is the resistivity of the signal trace 111, of the chip trace 112, or of the connector trace 113 (in ohms) L is the depth (measured vertically down) of the signal trace 111, of the chip trace 112, or of the connector trace 113 (unit is meter). A is the width (measured horizontally) of the signal trace 111, of the chip trace 112, or of the connector trace 113 (unit is the square meter). The signal traces 111, the chip traces 112, and the connector traces 113 are made of the same material, and have substantially the same depth, thus the impedance of the signal trace 111 is less than the impedance of the chip trace 112, while the impedance of the signal trace 111 is greater than the impedance of the connector trace 113.

The dielectric layer 12 supports the signal routing layer 11. The dielectric layer 12 is made up of insulating material(s). In this embodiment, the dielectric layer 12 is made of fiberglass mixed with resin. In alternative embodiments, ceramic powder is also mixed into the fiberglass and resin.

The dielectric layer 12 includes a signal trace area 121, a chip trace area 122, and a connector trace area 123. The signal trace area 121 carries the signal traces 111, the chip trace area 122 carries the chip traces 112, and the connector trace area 123 carries the connector traces 113. A depth of the connector trace area 123 in the dielectric layer 12 is the greatest, and a depth of the chip trace area 122 in the dielectric layer 12 is the smallest. In other words, a depth of the signal trace area 121 is less than the depth of the connector trace area 123 but is greater than the depth of the chip trace area 122.

Because the depth of the chip trace area 122 is less than the depth of the connector trace area 123, the impedance of the chip trace 112 spatially corresponding to the chip trace area 122 is reduced, the impedance of the connector traces 113 spatially corresponding to the connector trace area 123 is increased. Thus the impedance of the signal trace 111 spatially corresponding to the signal trace area 121 is substantially equal to that of the impedance of the chip trace 112 spatially corresponding to the chip trace area 122, and is substantially equal to that of the impedance of the connector traces 113 spatially corresponding to the connector trace area 123, so that the impedance of the signal routing layer 11 is consistent for an excellent signal transmitting ability.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A circuit board, comprising:
a signal routing layer comprising a plurality of connector traces, a plurality of chip traces, and a plurality of signal traces, each of the signal traces directly connecting to a respective one of the chip traces to a respective one of the connector traces, a width of the signal traces being greater than a width of the chip traces, while the width of the signal traces being less than a width of the connector traces;
a dielectric layer supporting the signal routing layer, the dielectric layer comprising a signal trace area carrying the signal traces, a chip trace area carrying the chip traces, and a connector trace area carrying the connector traces;
wherein a depth of the signal trace area is less than a depth of the connector trace area, while the depth of the signal trace area is greater than a depth of the chip trace area, so as to achieve an uniform impedance throughout all traces.

2. The circuit board of the claim 1, wherein the signal traces, the chip traces, and the connector traces are made of the same material, and have substantially the same depth.

3. The circuit board of claim 1, wherein a width of the signal traces is greater than a width of the chip traces, while the width of the signal traces is less than the width of the connector traces.

4. The circuit board of the claim 1, wherein the dielectric layer is made of fiberglass mixed with resin.

5. The circuit board of the claim 4, wherein the chip trace area of the dielectric layer comprises ceramic powder.

6. The circuit board of the claim 1, comprising a ground layer, wherein the ground layer is located on the dielectric layer.

7. The circuit board of the claim 1, wherein each of the signal traces is a single strip.

8. The circuit board of the claim 7, wherein each of the chip traces is a single strip.

9. The circuit board of the claim 8, wherein each of the connector traces is a single strip.
